(19) United States
(12) Patent Application Publication
(10) Pub. No.: US 2021/0289610 A1
(43) Pub. Date: Sep. 16, 2021

(54) FAILURE ANALYSIS APPARATUS USING X-RAYS

(71) Applicant: GLOBALFOUNDRIES U.S. INC., Santa Clara, CA (US)

(72) Inventor: MICHAEL HATZISTERGOS, Glenmont, NY (US)

(21) Appl. No.: 16/814,976

(22) Filed: Mar. 10, 2020

(51) Int. Cl. H05G 1/06; H05G 1/10

(52) U.S. Cl. CPC H05G 1/06; H05G 1/10

(57) ABSTRACT

An apparatus is provided, which includes a source, a holder, and a conductive member. The source generates an electron beam and the holder is configured to receive a sample. The conductive member is arranged between the source and the holder at a first position or a second position. The electron beam impinges on the sample to provide a first analysis reading when the conductive member is at the first position, and the electron beam impinges on the conductive member to emanate an X-ray beam on the sample to provide a second analysis reading when the conductive member is at the second position.

### FIELD OF THE INVENTION

The disclosed subject matter relates generally to a failure analysis apparatus and more particularly, to a failure analysis apparatus configured to provide an X-ray beam having a small spot size.

### BACKGROUND

As semiconductor technology is rapidly developing and the semiconductor devices become highly integrated, the role of surface analysis techniques has increased. Surface analysis techniques have important applications in the field of semiconductor chip fabrication, for example, an examination of microscopic defects at a surface layer can determine the root cause during failure analysis. Several surface analysis techniques are available each one with its own advantages and limitations.

Electron beam-based analysis techniques have several advantages over X-ray analytical techniques. For example, electron beams can achieve small spot sizes and thereby able to examine small feature sizes. However, when examining an insulating sample, charge accumulation may potentially alter or make the sample unstable (causing shifting peaks on the detected spectrum, arcing, etc.), diminishing the quality of images or even damaging the sample.

Therefore, insulating materials are generally examined using X-ray analytical techniques, such as X-ray photoelectron spectroscopy (XPS). However, in a typical laboratory setting, the X-ray spot size is large and is generally unable to accurately analyze small features.

Hence, there is a need to provide improved failure analysis techniques.

### SUMMARY

To achieve the foregoing and other aspects of the present disclosure, a failure analysis apparatus configured to provide an X-ray beam having a small spot size is presented.

According to an aspect of the present disclosure, an apparatus is provided, which includes a source, a holder, and a conductive member. The source generates an electron beam and the holder is configured to receive a sample. The conductive member is between the source and the holder at a first position or a second position. The electron beam impinges on the sample to provide a first analysis reading when the conductive member is at the first position, and the electron beam impinges on the conductive member to emanate an X-ray beam on the sample to provide a second analysis reading when the conductive member is at the second position.

According to another aspect of the present disclosure, a method of performing a failure analysis examination, which includes providing a source, a holder and a conductive member. The source generates an electron beam having a propagation path. The holder is configured to receive a sample and is movably configured to move the sample in the propagation path of the electron beam. The conductive member is arranged between the source and the sample. The conductive member is moved to a first position that is outside the propagation path of the electron beam to provide a first analysis reading and moved to a second position that is in the propagation path of the electron beam to provide a second analysis reading.

### BRIEF DESCRIPTION OF THE DRAWINGS

The embodiments of the present disclosure will be better understood from a reading of the following detailed description, taken in conjunction with the accompanying drawing:

FIGS. 1 and 2 are schematic arrangements of a failure analysis apparatus configured to provide an X-ray beam, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to a failure analysis apparatus configured to provide an X-ray beam having a small spot size. As used herein, “spot size” generally refers to a dimension measured laterally across a cross-section of a beam, in a plane substantially perpendicular to the propagation direction of the beam.

Various embodiments of the present disclosure are now described in detail with the accompanying drawing. The embodiments disclosed herein are exemplary, and not intended to be exhaustive or limiting to the disclosure.

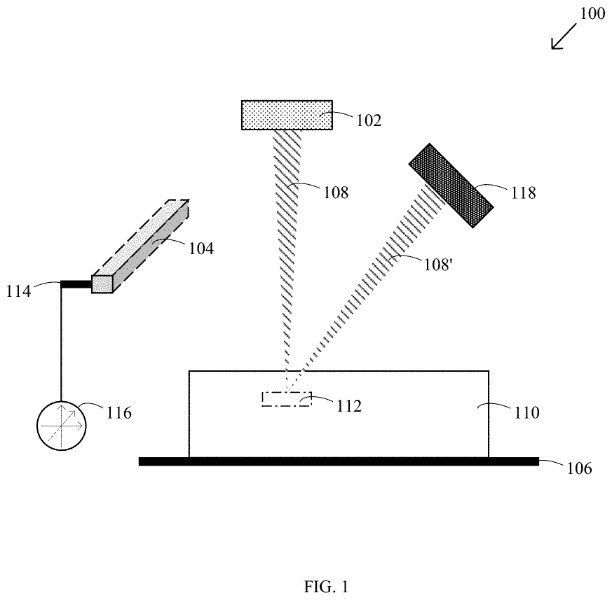

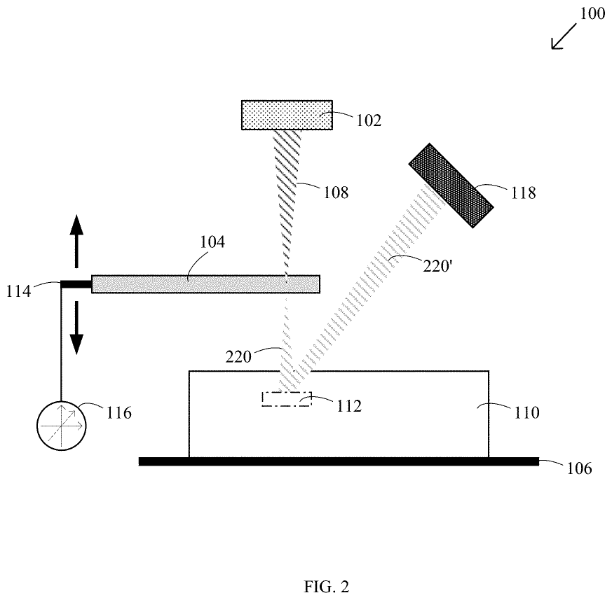

FIGS. 1 and 2 are schematic arrangements of a failure analysis apparatus 100, according to an embodiment of the disclosure. The apparatus 100 includes a source 102, a conductive member 104, and a sample holder 106.

The source 102 may be an electron-emitting source configured to emit an electron beam 108. The source 102 may be, for example, an electron gun. The emitted electron beam 108 has a propagation direction towards the sample holder 106.

The sample holder 106 is configured to receive a sample 110. The sample holder 106 may be positioned in a plane substantially perpendicular to the propagation path of the electron beam 108. During a surface analysis examination, the sample holder 106 is configured to move an area of interest 112 on the sample 110 in the propagation path of the electron beam 108.

The conductive member 104 may be detachably mountable between the source 102 and the sample holder 106 on a support structure 114. The conductive member 104 may be positioned in a plane substantially perpendicularly to the propagation direction of the electron beam 108. As used herein, the term “conductive member” refers to an electrically conductive material through which an electric current may flow into or out of the electrically conductive material.

In an embodiment of the disclosure, the conductive member may be selectively positioned with respect to the electron beam 108. For example, as illustrated in FIG. 1, the conductive member 104 may be positioned at a first position such that the conductive member 104 is laterally displaced from the propagation path of the incident electron beam 108, i.e., the incident electron beam 108 bypasses the conductive member 104 such that the incident electron beam 108 impinges onto the surface of the area of interest 112 on the sample 110. A signal 108′, such as a secondary electron beam, may be reflected from the surface of the area of interest 112 to a detector 118. The detector 118 is able to detect and process the signal 108′ to produce an image or spectra during the surface analysis examination.

In another example, as illustrated in FIG. 2, the conductive member 104 may be positioned at a second position such that the conductive member 104 is inserted in the propagation path of the incident electron beam 108 and the incident electron beam 108 impinges onto the conductive member 104. The conductive member 104, when bombarded with electrons from the incident electron beam 108, produces a beam of X-rays 220. The emanated X-ray beam 220 is projected onto the area of interest 112 on the sample 110. A signal 220′, such as a reflected X-ray beam, may be reflected from the surface of the area of interest 112 to the detector 118. The detector 118 is able to detect and process the signal 220′ to produce an image or spectra during the surface analysis examination.

In an embodiment of the disclosure, the conductive member 104 may be in a form of a planar structure, for example, a plate.

An X-ray analysis examination may be preferred for analyzing insulating materials as charges accumulating on the surface of the insulating sample is reduced as compared to an electron beam analysis examination. Accumulation of charges in insulating materials may affect the analysis and/or damage the composition or structure of the insulating materials.

The spot size of the incident electron beam 108 may be adjusted using a series of lenses (not shown). The series of lenses is capable of focusing the emitted electron beam 108 on the conductive member 104 or the sample 110 such that a small spot size is achieved.

The emanated X-ray beam 220 takes on the characteristics of the material forming the conductive member 104, for example, aluminum X-rays from an aluminum conductive member. Additionally, the type of X-rays emanated from the conductive member 104 is limited by the energy of the incident electron beam 108. Therefore, a conductive material may be selected as desired, coupled with preset energy of the electron beam 108, to generate a corresponding type of X-rays from the conductive member 104 to perform an X-ray analysis examination on the sample 110.

In an embodiment of the disclosure, the conductive member 104 may be a metallic material that includes metals such as, but not limited to, aluminum, magnesium, chromium, gold, alloys of these metals, and/or combinations thereof. As used herein, the term “metals” include not only elemental metals but metals having other trace elements or in various alloyed combinations with other elements as known in the art, as long as the chemical and physical properties of the metals remain substantially unaffected.

Additionally, according to other needs, the conductive member 104 may be selected from other conductive materials to obtain X-ray beams characteristic of that conductive material.

The emanated X-ray beam 220 has a small spot size by virtue of the small spot size of the incident electron beam 108 that impinges on the conductive member 104 when compared to a typical beam size in X-ray photoelectron spectroscopy (XPS). The emanated x-ray beam 220 may have a divergent path as illustrated in FIG. 2 and the spot size of the emanated X-ray beam 220 on the sample 110 may be expected to be larger than the spot size of the incident electron beam 108 on the conductive member 104. In an embodiment of the disclosure, the spot size of the emanated x-ray beam 220 is smaller than 5 um.

In an embodiment of the disclosure, the conductive member 104 is additionally movably configured to be selectively positioned with respect to the sample 110. The conductive member 104 may be configured to move closer to the sample 110 (illustrated by a downward arrow in FIG. 2) or further from the sample 110 (illustrated by an upward arrow in FIG. 2) when the conductive member 104 is inserted in the propagation path of the incident electron beam 108.

As the emanated X-ray beam 220 may be projected at the sample 110 in a divergent path, by adjusting the position of the conductive member 104 with respect to the sample 110, the spot size of the emanated X-ray beam 220 may be adjusted accordingly. For example, a smaller X-ray beam spot size may be achieved when the conductive member 104 is adjusted closer to the sample 110, and accordingly, a larger X-ray beam spot size may be achieved when the conductive member 104 is adjusted further from the sample 110. Thus, depending on the size of the area of interest 112 on the sample 110 to be analyzed, the spot size of the emanated X-ray beam 220 can be adjusted accordingly.

It is preferable to achieve an X-ray beam spot size that is substantially similar to the area of interest 112 on the sample 110 to be analyzed. Having an X-ray beam spot size larger than the area of interest 112 may cause the analysis to inaccurately include data points outside of the area of interest 112.

In an embodiment of the disclosure, the apparatus 100 may include a control mechanism 116 to selectively position the conductive member 104. The control mechanism 116 may have means to move the conductive member 104 in and out of the propagation path of the incident electron beam 108 and may have means to adjust the position of the conductive member 104 with respect to the sample 110.

In an embodiment of the disclosure, the conductive member 104 may be a modular unit that can be externally equipped to an electron beam analysis system, such as a scanning electron microscope (SEM) or an Auger electron spectroscopy system (AES). The conductive member 104 may be, for example, retrofitted onto an existing electron beam analysis system to advantageously expand the functionality of the electron beam analysis system to include the function of an X-ray analysis system by using the electron beam emitted by the electron beam analysis system. The X-ray analysis system may include an X-ray photoelectron spectroscopy (XPS) system.

Therefore, the electron beam analysis system can be used to analyze insulating samples using the emanated X-ray beam 220 from the conductive member 104 when the conductive member 104 is inserted in the path of the incident electron beam 108. A small X-ray beam spot size can be achieved with this setup. The composition and structural integrity of the insulating sample may be substantially maintained as charge buildup in the sample is reduced.

As presented in the above detailed description, a failure analysis apparatus capable of providing an X-ray beam having a small spot size is presented. The apparatus includes an electron-emitting source, movably configured sample holder and a conductive member.

The conductive member is movably positioned between the source and the sample holder. The conductive member may be detachably mounted and selectively positioned at a first position or at a second position. At the first position, the conductive member is arranged outside the propagation path of an electron beam such that the electron beam impinges on the sample to provide a first analysis reading. At the second position, the conductive member is arranged in the propagation path of the electron beam such that the electron beam impinges on the conductive member to emanate an X-ray beam and the emanated X-ray beam is used to provide a second analysis reading from the sample.

The spot size of the emanated X-ray beam from the conductive member is expected to be small by virtue of the small spot size of the electron beam when compared to a typical X-ray analysis system. As the spot sizes of electron beams can be controlled using a series of lenses, the spot sizes of the emanated X-ray beam may, accordingly, be adjusted.

As the semiconductor industry continues to progress with greater device miniaturization, the ability of surface analysis techniques to analyze progressively smaller features is instrumental in detecting microscopic defects in the chips. Although synchrotrons can produce small X-ray spot sizes, such equipment is huge and not easily accessible. The failure analysis apparatus presented in the present disclosure is configured to provide an X-ray beam having a small spot size and easily set up in a typical laboratory setting.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

The terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

While an exemplary embodiment has been presented in the above detailed description of the apparatus, it should be appreciated that a number of variations exist. It should further be appreciated that the embodiment is only an example, and is not intended to limit the scope, applicability, dimensions, or configuration of the apparatus in any way. Rather, the above detailed description will provide those skilled in the art with a convenient road map for implementing an exemplary embodiment of the apparatus, it being understood that various changes may be made in the function and arrangement of elements described in an exemplary embodiment without departing from the scope of this disclosure as set forth in the appended claims.

What is claimed is:

1. An apparatus comprising:
a source for generating an electron beam;
a holder for receiving a sample; and
a conductive member arranged between the source and the holder, wherein when the conductive member is arranged at a first position, the electron beam impinges on the sample to provide a first analysis reading and when the conductive member is arranged at a second position, the electron beam impinges on the conductive member to emanate an X-ray beam on the sample to provide a second analysis reading.

2. The apparatus of claim 1, wherein the emanated X-ray beam has a spot size smaller than 5 um.

3. The apparatus of claim 1, wherein the emanated X-ray beam has a spot size larger than that of the electron beam when providing the second analysis reading.

4. The apparatus of claim 1, wherein the emanated X-ray beam comprises X-ray beams characteristic of the conductive member.

5. The apparatus of claim 1, wherein the conductive member comprises a metallic material.

6. The apparatus of claim 1, wherein the first analysis reading comprises an electron beam-based analysis reading.

7. The apparatus of claim 1, wherein the first analysis reading comprises a scanning electron microscopy reading or an Auger electron spectroscopy reading.

8. The apparatus of claim 1, wherein the second analysis reading comprises an X-ray-based analysis reading.

9. The apparatus of claim 1, wherein the second analysis reading comprises an X-ray photoelectron spectroscopy reading.

10. The apparatus of claim 1, further comprises a control mechanism, wherein the control mechanism is configured to move the conductive member along a longitudinal axis of the X-ray beam.

11. The apparatus of claim 1, further comprises a control mechanism, wherein the control mechanism is configured to displace the conductive member from the first position to the second position or from the second position to the first position.

12. The apparatus of claim 1, wherein the conductive member is configured to be detachably mountable onto a support structure of the apparatus.

13. The apparatus of claim 1, wherein the conductive member is movably configured to move closer or further from the sample.

14. The apparatus of claim 1, wherein the conductive member comprises aluminum.

15. The apparatus of claim 1, wherein the conductive member comprises magnesium.

16. The apparatus of claim 1, wherein the conductive member comprises chromium.

17. The apparatus of claim 1, wherein the conductive member comprises gold.

18. A method of performing a failure analysis examination comprising:
providing a source for generating an electron beam having a propagation path;
providing a holder for receiving a sample, wherein the holder is movably configured to move the sample in the propagation path of the electron beam;
providing a conductive member between the source and the holder;
moving the conductive member to a first position that is outside the propagation path of the electron beam to provide a first analysis reading; and
moving the conductive member to a second position that is in the propagation path of the electron beam to provide a second analysis reading.

19. The method of claim 18, wherein the second analysis reading is provided by an X-ray beam emanated from the conductive member.

20. The method of claim 18, wherein the conductive member comprises a metallic material.
